(19) United States
(12) Patent Application Publication
(10) Pub. No.: US 2017/0365492 A1
(43) Pub. Date: Dec. 21, 2017

(54) WAFER PROCESSOR DOOR INTERFACE

(71) Applicant: APPLIED Materials, Inc., Santa Clara, CA (US)

(72) Inventors: Kyle Moran Hanson, Kalispell, MT (US); Paul R. McHugh, Kalispell, MT (US)

(21) Appl. No.: 15/604,312

(22) Filed: May 24, 2017

Related U.S. Application Data
(60) Provisional application No. 62/350,809, filed on Jun. 16, 2016.

(51) Int. Cl. H01L 21/67; B08B 3/08; H01L 21/02; H01L 21/687; B08B 3/04

(52) U.S. Cl. CPC H01L 21/67051; H01L 21/68785; H01L 21/68771; B08B 3/042; H01L 21/02041; B08B 3/08; H01L 21/68764

(57) ABSTRACT

A processing system includes at least one processor having a tank for holding a process liquid. A clean assembly above the tank is provided with an upper housing having at least one upper housing spray nozzle, and a lower housing having at least one lower housing spray nozzle, with the lower housing below the upper housing. A door between the upper housing and the lower housing is movable via an actuator from an open position wherein a load port through the clean assembly is open, to a closed position wherein the load port is closed off. The door largely prevents liquids used in the upper housing from moving down into the process liquid in the tank, and may also improve gas flow in the system.

### PRIORITY CLAIM

This application claims priority to U.S. Provisional Patent Application No. 62/350,809, filed Jun. 16, 2016, and now pending.

### FIELD OF THE INVENTION

The field of the invention is processors, systems, and methods for processing semiconductor material wafers, and similar workpieces or substrates for microelectronic devices.

### BACKGROUND OF THE INVENTION

Microelectronic devices, such as semiconductor devices, are generally fabricated on and/or in silicon or other semiconductor material wafers. Patterned layers are formed on the wafer surface via photolithography. Photoresist used in the photolithography steps is removed by chemical stripping. This may be a relatively time consuming process where the wafers are immersed in a bath of heated solvent, for example in a wet bench or other apparatus. The solvent (or other process liquid) must be removed from the wafers after the chemical stripping step without contaminating the manufacturing environment, and advantageously also without diluting the bath of heated solvent with rinsing or cleaning liquids.

Accordingly, engineering challenges remain in providing systems and methods for processing wafers.

### SUMMARY OF THE INVENTION

A wafer processing system includes at least one processor having a tank for holding a process liquid. A clean assembly above the tank is provided with an upper housing having at least one upper housing spray nozzle, and a lower housing having at least one lower housing spray nozzle, with the lower housing below the upper housing. A door between the upper housing and the lower housing is movable via an actuator from an open position wherein a load port through the clean assembly is open, to a closed position wherein the load port is closed off. The door largely prevents liquids used in the upper housing from moving down into the process liquid in the tank, and may also improve gas flow in the system.

### BRIEF DESCRIPTION OF THE DRAWINGS

In the drawings:

FIG. 1 is a perspective view of processing system.

FIG. 2 is a side view of the system shown in FIG. 1.

FIG. 3 is a perspective view of the tank of the system shown in FIGS. 1 and 2.

FIG. 4 is a section view taken along line 4-4 of FIG. 3.

FIG. 5 is a perspective view of the head shown in FIGS. 1 and 2.

FIG. 6 is a top perspective view of an alternative clean assembly having a door in the closed position.

FIG. 7 is a perspective section view of the clean assembly as shown in FIG. 6.

FIG. 8 is a side section view of the clean assembly as shown in FIGS. 6 and 7.

FIG. 9 is a side section view of the clean assembly of FIGS. 6-7 with the door in the open position.

FIG. 10 is a perspective view of an alternative design.

FIG. 11 is an enlarged side view of the design of FIG. 10 with the door in the closed position.

### DETAILED DESCRIPTION

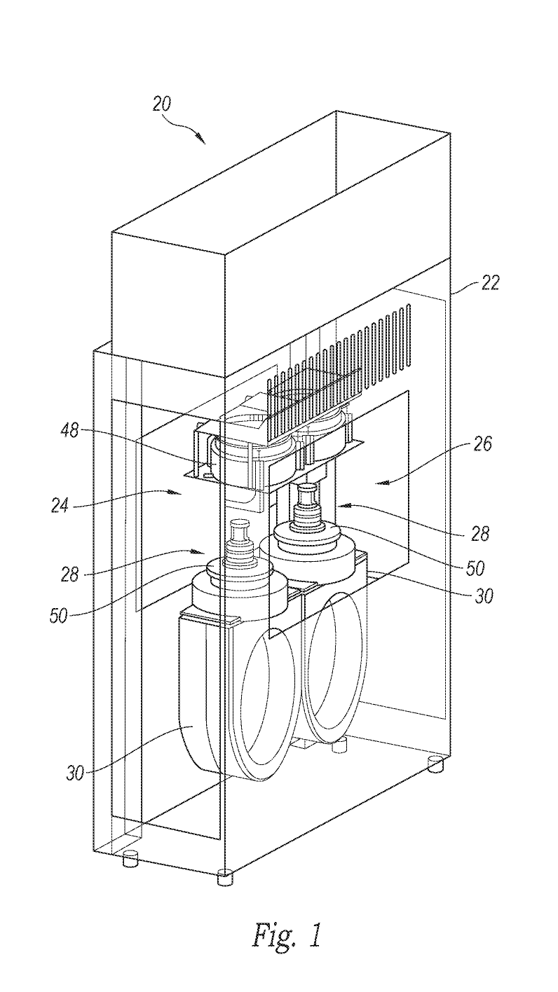

As shown in FIG. 1, a processing system 20 has first and second wafer processors 28 within an enclosure 22. The enclosure 22 may have access openings 24 and 26 to allow workpieces, such as semiconductor wafers, to be moved into and out of the processing system 20, typically via robots. The access openings 24 and 26 may have closures, such as movable panels or windows, for closing off the access openings 24 and 26 during processing, to better contain vapors or gases within the enclosure 22. The enclosure 22 may also be provided with air inlets and exhaust connections, to provide a controlled flow of air through the enclosure.

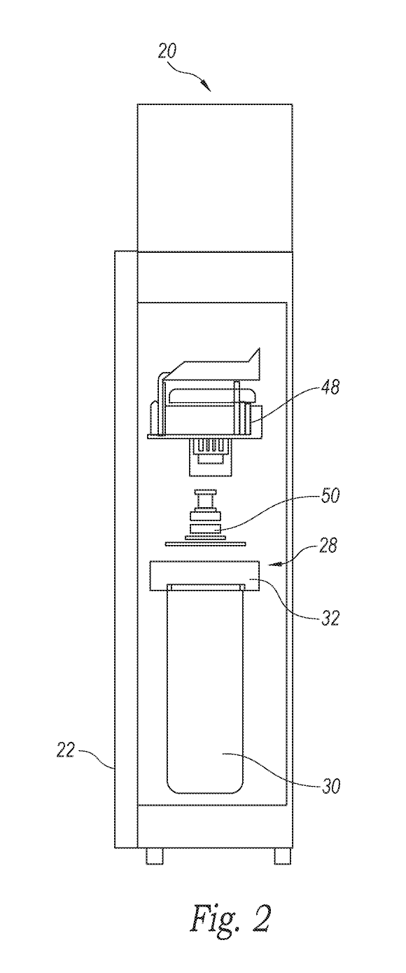

As shown in FIGS. 1 and 2, each processor 28 has a head 50 for loading wafers 100 into and out of a process tank 30. Depending on the specific process performed, a secondary chamber 48, such as a spin rinser dryer, may be associated with each processor 28 within the enclosure.

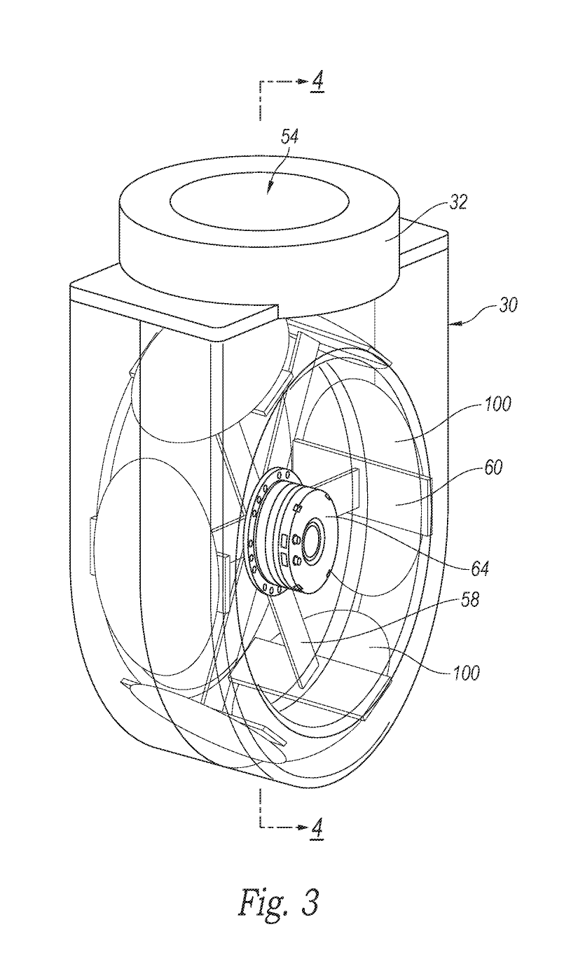

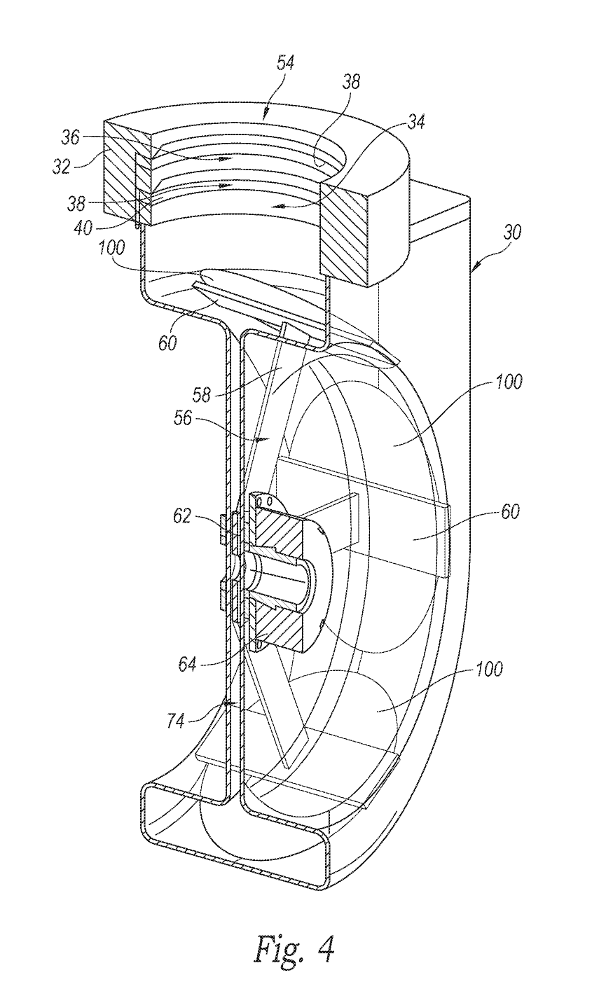

Turning now to FIGS. 3 and 4, a clean assembly 32 is provided at the top of the process tank 30. The clean assembly 32, if used, generally includes clean housing 34 surrounded by a lower or clean housing drain channel 40, and a rinse housing 36 surrounded by an upper or rinse housing drain channel 38. The drain channels 38 and 40 are connected to a facility drain and optionally to a vacuum source. The process tank also includes one or more liquid inlets and one or more liquid drains, for filling and draining the process liquid, or providing a flow of process liquid through the process tank.

As best shown in FIG. 4, a rotor 56 in the process tank 30 has a plurality of arms 58 extending radially outward from a central hub 62, with a holder 60 at the outer end of each arm 58. A motor 64 is connected to the rotor 56 for rotating the rotor 56 in the process tank 30.

In use, a process liquid, generally a solvent, for example dimethyl sulfoxide (DMSO), is pumped into the process tank 30 so that the process tank 30 is filled to e.g., 50 to 90% of capacity. The head 50 holding a wafer 100 is lowered down into a load port 54 at the top of the process tank 30. The head 50 hands the wafer 100 off to a holder 60 on the rotor 56. The holder 60 engages the backside and/or edge of the wafer 100, with the front or device side of the wafer 100 facing up. The motor 64 is actuated to rotate the rotor 56 moving the wafer 100 in a circular path through the process liquid in the process tank 30. With this movement, a subsequent holder 60 moves into the load port 54 to receive a subsequent wafer 100.

The motor 64 rotates the rotor 56 at a rate that allows the wafer 100 to remain submerged in the process liquid for a time interval sufficient to complete processing the wafer, typically 1 to 30 minutes. As the rotor 56 continues to rotate, the processed wafer 100 returns to the load port 54 and is removed from the process tank via the head 50. Subsequent wafers 100 are similarly processed.

Depending on the specific process and process liquid used, the wafer 100 may then be rinsed in the rinse housing 36, to remove residual process liquid. A first liquid used as a rinse liquid may be sprayed onto the wafer from rinse nozzles in the rinse housing 36, and/or on the head 50. Generally the head 50 also spins the wafer 100 to fling off rinse liquid. In an optional second step performed within the clean assembly 32, the head may lift the wafer 100 up into the clean housing 34 where the wafer is further cleaned via a spray of a second liquid or a cleaning liquid, such as de-ionized water and/or dried. For applications such as photoresist strip where the process liquid is a solvent, the wafer 100 may be further cleaned and dried via the secondary chamber 48 such as a spin rinser dryer. The wafer 100 is then moved out of the enclosure 22 for further handling or processing. Operations of the system 20 and the process tank 30 are typically controlled via computer, to provide more uniform processing.

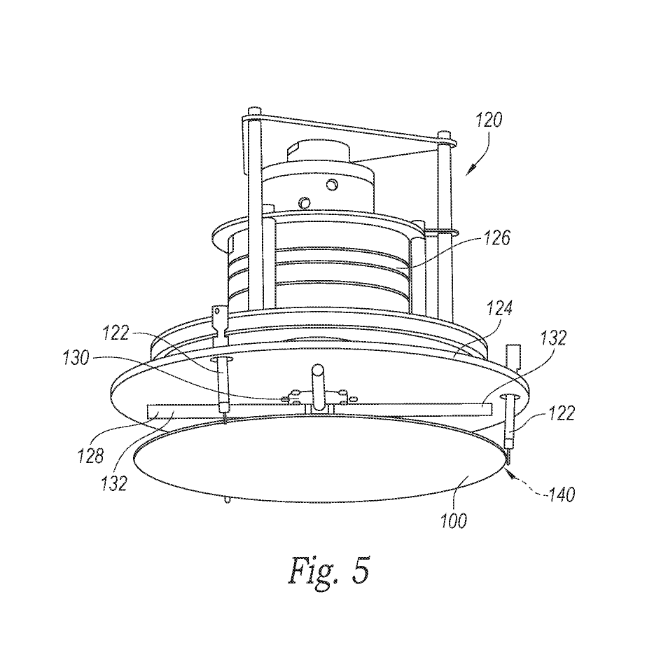

FIG. 5 shows an alternative head 120 similar to the head 50 and having fingers 122 on a head rotor 124 adapted to hold a wafer 100 at a wafer holding position generally shown at 140, typically several centimeters below the head rotor 124 of the head 120. A head motor 126 on the head 120 rotates the head rotor 124. Rinse arms 128 extend out from a rinse hub 130 attached to the frame of the head 120, which does not rotate. Rinse nozzles 132 on the rinse arms 128 are aimed at the wafer holding position. In use, with a wafer held in the wafer holding position, rinse liquid is pumped through the rinse hub 130 and the rinse arms 128 to the rinse nozzles, to rinse the up-facing front side of the wafer 100.

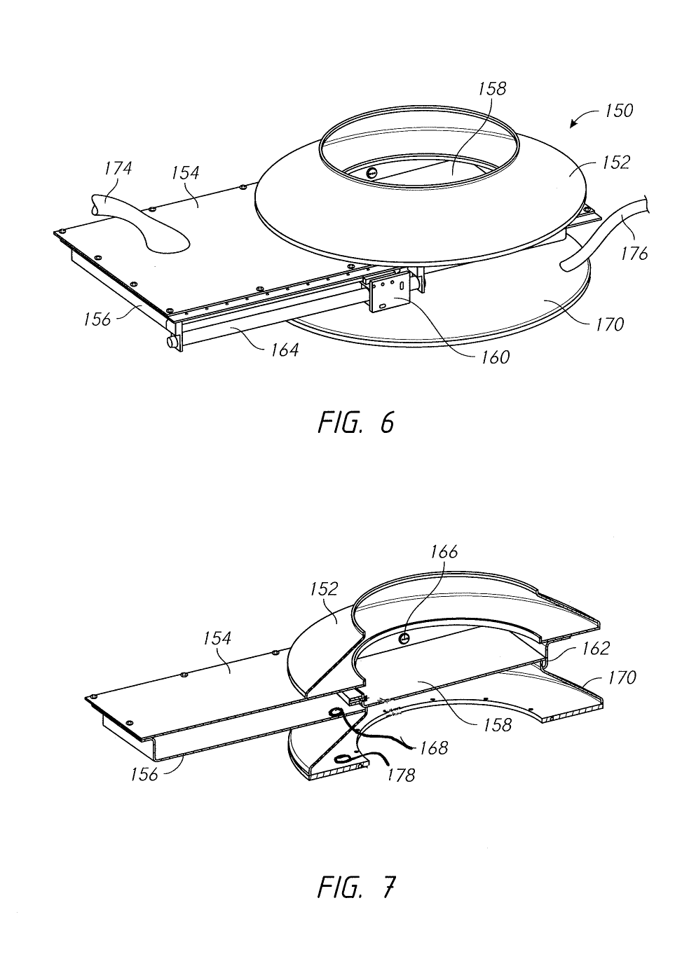

FIGS. 6-9 show an alternative clean assembly 150 which may be used in place of the clean assembly 32 shown in FIGS. 3 and 4. As shown in FIGS. 6 and 7, the clean assembly 150 has an upper or first housing 152 on top of a deck plate 154. A door 158 is movable horizontally in a door housing 156 to open and closed positions via a door actuator 160. The door 158 may be provided as a rectangular flat plate having a round opening generally matching the diameter of the load port 54 shown in FIG. 4. The door 158 may be supported on a linear bearing 164. If the process liquid in the tank 30 evolves vapors, for example when the process liquid is a solvent heated to 110 to 120° C., an exhaust line 174 from the door housing 156 may connect to a facility exhaust or vacuum source, to draw off the vapors, with a flow rate of e.g., 500 to 900 liters per minute. A short upright leg 159 may be provided at the back end of the door 158 for attaching the door 158 to the door actuator 160, and/or for directing air flow through the door housing 156. The door 158 may be spaced vertically apart from the upper and lower surfaces of the door housing 156 to allow air to flow through the door housing 156 both above and below the door 158 when the door is in the open position.

A lower housing or a second housing 170 is positioned on top of and attached onto the process tank 30. The lower housing 170 may have the same size and shape as the upper housing 152. Both housings 152 and 170 have a conically tapering sidewall, as shown in FIGS. 7-9, to guide liquid flung off of the wafer 100 to a drain 168. Both housings 152 and 170 also have a circular central opening aligned on a common central vertical axis, to allow the head 50 or 120 to move vertically through the clean assembly 150, to load and unload wafers 100 into and out of the tank 30. A purge gas line 176 may provide a purge gas, such as nitrogen into the lower housing 170, for example at a rate of 20 to 40 liters per minute.

As shown in FIG. 7, an angled rim 162 is provided on the floor of the door housing 156 within the upper housing 152. The height of the angled rim 162 is greater at the distal side (the right side in FIGS. 7-9) than at the proximal side (the left side in FIGS. 7-9), with the top surface of the angled rim 162 providing an annular angled door seating surface. As shown in FIG. 9, the door 158 is oriented at a slight inclination angle (inclined from proximal side to the distal side). With the door in the open position as shown in FIG. 9, the angled seating surface provides spacing between the bottom surface of the door 158 and the angled rim 162. As a result, the door 158 does not slide or scrape against the angled seating surface during door movement.

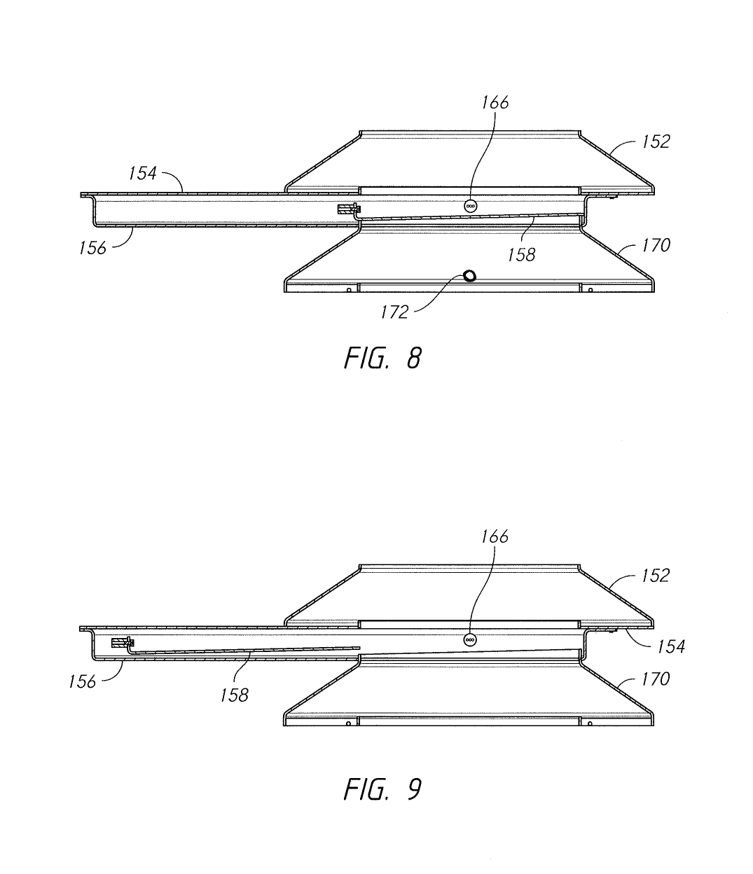

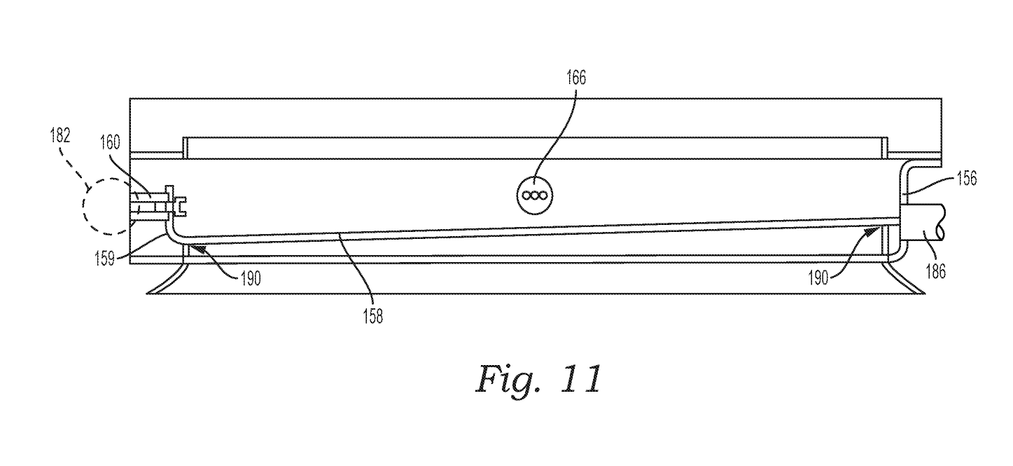

With the door 158 in the closed position, as shown in FIGS. 7 and 8, the angled seating surface provides near contact at the end of travel to limit the gap 190 shown in FIG. 11, between the door and the angled rim 162 to reduce evaporation from the tank 30 and to reduce egress of ambient air into the tank 30. The door 158 need not actually seal with the angled rim 162 when in the closed position. In the design shown, the door in the closed position closes off the load port, but does not seal the load port. Rather, when in the closed position the door 158 may fully or partially contact the angled rim 162, or be spaced apart from the angled rim 162 by a the gap 190 of e.g., 0.5 to 1 mm. As a result, even with the door 158 in the closed position, the exhaust line 174 continues to draw off vapors from the process liquid in the tank 30, along with purge gas, if used, although at a reduce flow rate in comparison to the flow rate when the door 158 is open. In designs where the door 158 closes off, but does not seal the load port 54, no resilient seal components such as O-rings, gaskets, etc. are needed, and the door 158 is not positively forced against the angled rim 162 or other surface. Maintenance requirements are therefore reduced, especially wherein the process liquid, e.g., a heated solvent, is chemically reactive.

In a typical operation, the door 158 is moved via the door actuator 160 to the open position shown in FIG. 9. The head 50 or 120 moves vertically down through the clean assembly 150 and transfers a wafer 100 onto a holder 60 aligned under the load port 54. The holder 60 may have active actuator driven fingers or other elements for holding the edge of the wafer 100. Alternatively, the holder 60 may have passive elements which are moved via interaction with the head 50 or 120, for grasping and holding the wafer.

The motor 64 rotates the rotor 56 to move a processed wafer into alignment with the load port 54, and the head 50 or 120 picks up the processed wafer. The head then moves up to position the processed wafer in the lower housing 170. The door 158 remains in the open position. A lower spray nozzle 172 in the lower housing 170 sprays a rinse liquid onto the wafer 100 while the head 50 or 120 rotates the wafer 100, to remove residual process liquid from the wafer. Particles on the wafer 100, such as pieces of solid photoresist etched off of the wafer 100, are also removed. The angled side walls and the floor of the lower housing 170 guide and collect liquid flung off of the wafer. If the rinse liquid is the same as the liquid in the tank, then this collected liquid may be allowed to flow back into the tank. If the rinse liquid is different from the liquid in the tank, then this collected liquid may be removed from the lower housing 170 via a lower housing drain line 178 shown in FIG. 7, which is connected to a facility drain.

During this rinse process with the wafer 100 in the lower housing 170, if used, purge gas is pumped into the lower housing 170 via the purge gas line 176, and the exhaust line 174 is also on. As a result, vapors evolved from the process liquid in the tank 30 are removed largely via the exhaust line 174, and ambient air is prevented from flowing into the tank and reacting with the process liquid, largely via the purge gas flow the combination of the purge gas flow and the small gap 190 between the lid and the top of the lower housing 170.

The head 50 or 120 then moves up to position the wafer 100 in the upper housing 152. The door actuator 160 closes the door 158. The purge and exhaust lines, if used, remain on. The upper spray nozzle 166 sprays a cleaning liquid, such as de-ionized water, onto the wafer 100 while the head rotates the wafer. The used cleaning liquid is collected are removed from the upper housing 152 via the drain 168. As with the clean assembly 32 shown in FIGS. 3-4, in using the clean assembly 150, following the steps described above, the wafer 100 may then be further cleaned and dried via the secondary chamber 48 such as a spin rinser dryer. The wafer 100 is then moved out of the enclosure 22 for further handling or processing.

The door in the closed position prevents the cleaning liquid from moving into the tank 30 and may also help to efficiently exhaust vapors from the tank 30 and limit evaporation of the process liquid. Correspondingly, with the system 20 in the idle state, the door 158 is closed and the purge and exhaust lines are on. The door 158 in the closed position also closes off the load port 54, preventing any access or line of sight into the tank 30. The head 50 or the rotor 56 may have a diameter 1-6 mm less than the diameter of the load port 54, so that even with the door open, there is substantially no line of sight into the tank 30 when the head is below the level of the door 158 during the loading/unloading and cleaning steps.

The load port 54 of the clean assembly 32 discussed above relative to FIGS. 3 and 4 may similarly have a load port door movable from a first position wherein the load port door closes off and seals the load port, to a second position wherein the load port is open.

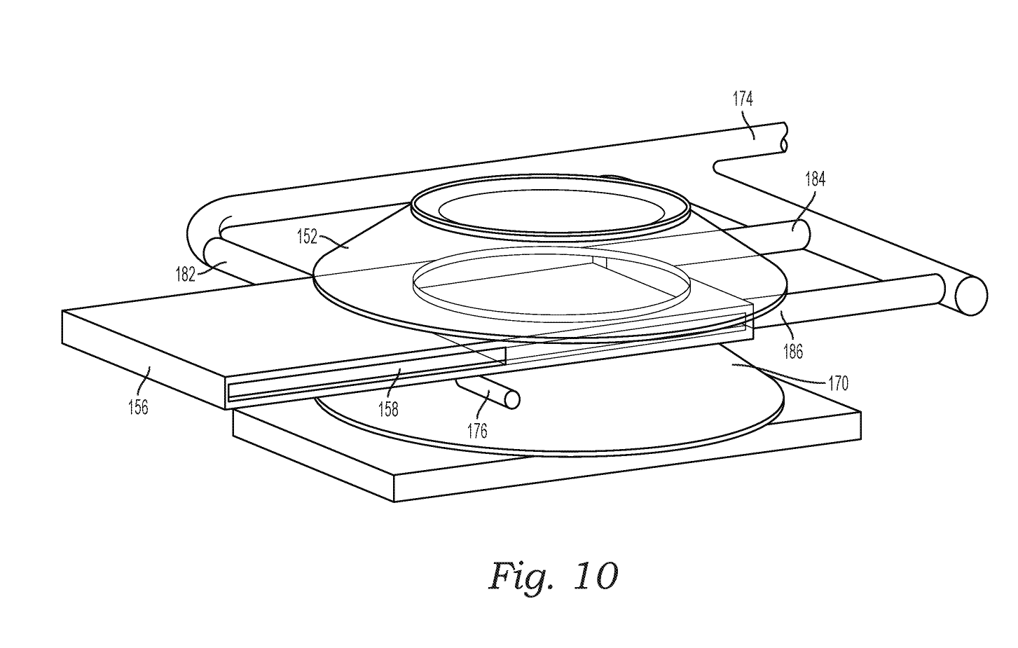

In an alternative design shown in FIGS. 10 and 11, a first exhaust port 182 is provided near a mid-point of the door housing 156, and a second exhaust port 184 and a third exhaust port 186 connect into the front end of the door housing 156. The exhaust ports 184 and 186 may be vertically positioned so that when the door 158 is closed, the exhaust ports 184 and 186 draw in air from above and from the below the door 158. For example the door 158 may be positioned at the vertical centerline of the exhaust ports 184 and 186. Also as shown in FIG. 10, the purge gas line 176 may intersect into the lower housing 170 at an off-center position to avoid directly impinging purge gas onto a wafer in the lower housing 170, reducing potential for particle contamination of the wafer. The purge gas line 176 as well as the exhaust ports are located off to one side of the tank 30, and not directly over the tank 30, to reduce evaporation from the tank.

The processing system 20 described above effectively contains vapors with the door 158 closed, and the head 50 out of the tank 30 or with the head 50 holding a wafer in the upper housing 152, as well as with the door 158 open with the head 50 out of the tank 30, or with the head 50 holding a wafer in the lower housing 170 or the with the head in the fully down position for loading or unloading a wafer into or out of the tank 30.

As used here, wafer refers collectively to silicon or other semiconductor material wafers, as well as other substrates on which micro-scale devices are formed. Thus, novel methods and systems have been shown and described. Various changes and substitutions may of course be made without departing from the spirit and scope of the invention. The invention, therefore, should not be limited, except by the following claims and their equivalents.

1. A processing system, comprising:
a processor having a tank for holding a process liquid;
a clean assembly above the tank, with the clean assembly including:
an upper housing having at least one upper housing spray nozzle;
a lower housing having at least one lower housing spray nozzle, with the lower housing below the upper housing;
a door between the upper housing and the lower housing, with the door movable from an open position wherein a load port through the clean assembly is open, to a closed position wherein the load port is closed off; and
an actuator attached to the door for moving the door into the open position and into the closed position.

2. The processing system of claim 1 wherein the door comprises a flat plate oriented at an inclination angle.

3. The processing system of claim 2 further comprising a rim in the lower housing having an annular door seating surface oriented at the inclination angle.

4. The processing system of claim 1 further comprising a door housing between the upper housing and the lower housing, with the door movable horizontally within the door housing.

5. The processing system of claim 4 further including at least one exhaust line connecting into the door housing.

6. The processing system of claim 5 including a first exhaust line connecting into a first side of the door housing and one or more second exhaust lines connecting into a second side of the door housing.

7. The processing system of claim 5 further comprising a purge gas line which connects into the lower housing.

8. The processing system of claim 1 with upper the upper housing and the lower housing each having a conically tapering sidewall.

9. The processing system of claim 4 further including a deck plate on the door housing, with the door between the deck plate and the door housing when the door is in the closed position.

10. The processing system of claim 9 with the load port provided via a circular through opening in each of the upper housing, the lower housing, the deck plate and the door housing, with the circular through openings aligned on a central axis.

11. The processing system of claim 10 wherein the door in the closed position closes off, but does not seal, the load port.

12. A wafer processing system comprising:
a process tank;
a clean assembly at an upper end of the process tank;
a head having a head rotor adapted to hold a wafer, with the head movable vertically through a load port in the clean assembly to load and unload a wafer into and out of the process tank; and
the clean assembly having a load port door movable from a first position wherein the load port door closes off the load port, to a second position wherein the load port is open.

13. The wafer processing system of claim 12 with the clean assembly including an upper housing having at least one upper housing spray nozzle, and a lower housing having at least one lower housing spray nozzle, with the lower housing below the upper housing.

14. The wafer processing system of claim 12 wherein the door comprises a flat plate oriented at an inclination angle, further comprising a door actuator attached to the door for moving the door horizontally into the first position and into the second position.

15. The wafer processing system of claim 14 further comprising a rim in the lower housing having an annular door seating surface oriented at the inclination angle.

16. The wafer processing system of claim 13 with the door in a door housing between the upper housing and the lower housing, an exhaust line connecting into the door housing, and a purge gas line which connects into the lower housing.

17. A method for processing a wafer, comprising:
filling a process tank at partially with a process liquid;
opening a door of a clean assembly above the process tank;
moving a head down through a load port in the clean assembly;
processing the wafer with the wafer immersed in the process liquid;
moving the processed wafer up out of the process liquid and into a first housing in the clean assembly;
spraying a first liquid onto the processed wafer;
moving the wafer up out of the first housing of the clean assembly and into a second housing of the clean assembly;
closing the door; and
spraying a second liquid onto the processed wafer.

18. The method of claim 17 further including rotating the wafer in the first housing and in the second housing.

19. The method of claim 18 wherein the first liquid is the process liquid.

20. The method of claim 17 further including providing a purge gas into the tank above the process liquid, with the clean assembly connected to a vacuum source.
